(19) United States
(12) Patent Application Publication
(10) Pub. No.: US 2024/0297017 A1
(43) Pub. Date: Sep. 5, 2024

(54) JET IMPINGEMENT COOLING ASSEMBLY FOR PLASMA WINDOWS POSITIONED IN A BEAM ACCELERATOR SYSTEM

(71) Applicant: SHINE Technologies, LLC, Janesville, WI (US)

(72) Inventors: Preston Barrows, Madison, WI (US); Tye Gribb, Fitchburg, WI (US)

(21) Appl. No.: 18/116,036

(22) Filed: Mar. 1, 2023

(51) Int. Cl. H01J 37/317; H01J 37/32; H01J 37/34

(52) U.S. Cl. CPC H01J 37/3171; H01J 37/3244; H01J 37/3447; H01J 2237/002

(57) ABSTRACT

A beam accelerator system comprises an ion accelerator that generates an ion beam, a low-pressure chamber, an anode, a plasma window, and a cathode housing. The plasma window comprises a plurality of cooling plates. Each cooling plate comprises a central wall surrounding the aperture, a cooling chamber surrounding the central wall, one or more impingement channels, and one or more return channels. Each of the impingement channels and return channels enter the cooling plate from an outer edge of the cooling plate and extend toward the aperture to the cooling chamber. Each of the one or more impingement channels are configured to provide an entrance pathway for cooling fluid to enter the cooling chamber and each of the one or more return channels are configured to provide an exit pathway for heated fluid to exit the cooling chamber.

### STATEMENT REGARDING FEDERALLY SPONSORED RESEARCH AND DEVELOPMENT

The present disclosure was developed with Government support under Contract No. DE-AR0001377 awarded by the United States Department of Energy. The Government has certain rights in the present disclosure.

### BACKGROUND

### Field

The present specification generally relates to cooling plates for plasma window systems, particularly plasma window systems used in a beam accelerator system, such as, for example, a gaseous-target neutron generation system.

### Technical Background

Beam accelerator systems are used to produce medical-grade radioactive isotopes used by doctors in nuclear medicine. Generally speaking, beam accelerator systems include an ion accelerator that generates a high-energy ion beam that is directed to a target chamber through a plasma window. For instance, in gaseous-target neutron generation systems, a high-energy ion beam is directed to a gaseous target. The generation and movement of the high-energy ion beam to the target requires a significant amount of energy and generates a significant amount of heat.

Accordingly, a need exists for components of beam accelerator systems, such as gaseous-target neutron generation systems, that help reduce the cost and energy required to generate neutrons and, potentially, radioactive isotopes.

### SUMMARY

According to one embodiment, a beam accelerator system comprises: an ion accelerator that generates an ion beam; a low-pressure chamber; an anode adjacent and fluidly connected to the low-pressure chamber; a plasma window adjacent and fluidly connected to the anode; and a cathode housing adjacent and fluidly connected to the plasma window, wherein the plasma window comprises a plurality of cooling plates, each cooling plate comprises an aperture that is aligned with an aperture in one or more adjacent cooling plate to form a plasma channel, and one or more cooling plates of the plurality of cooling plates comprises: a central wall surrounding the aperture; a cooling chamber surrounding the central wall; one or more impingement channels entering the cooling plate from an outer edge of the cooling plate and extending toward the aperture to the cooling chamber; and one or more return channels entering the cooling plate from the outer edge of the cooling plate and extending toward the aperture to the cooling chamber, wherein each of the one or more impingement channels are configured to provide an entrance pathway for cooling fluid to enter the cooling chamber and each of the one or more return channels are configured to provide an exit pathway for heated fluid to exit the cooling chamber.

According to one embodiment, a method comprises: generating a plasma in a plasma channel of a plasma window, wherein: the plasma window is positioned between and fluidly coupled to an anode and a cathode housing, a plurality of cathodes are housed in the cathode housing; the plasma window comprises a plurality of cooling plates, each cooling plate comprises an aperture that is aligned with an aperture in one or more adjacent cooling plate to form the plasma channel, and one or more cooling plates of the plurality of cooling plates comprises: a central wall surrounding the aperture; a cooling chamber surrounding the central wall; one or more impingement channels entering the cooling plate from an outer edge of the cooling plate and extending toward the aperture to the cooling chamber; and one or more return channels entering the cooling plate from the outer edge of the cooling plate and extending toward the aperture to the cooling chamber, directing an ion beam generated by an ion accelerator from a low-pressure chamber through the plasma disposed in the plasma channel of the plasma window and into a target chamber, wherein the target chamber houses a target gas; and directing a cooling fluid through the one or more impingement channels such that the cooling fluid impinges the central wall, transferring heat from the central wall to the cooling fluid, which then flows as a heated cooling fluid into the one or more return channels.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a gaseous target neutron generation system according to embodiments disclosed and described herein;

FIG. 2A schematically depicts a low pressure chamber, anode, plasma window, cathode housing, and cathodes according to embodiments disclosed and described herein;

FIG. 2B schematically depicts a cross-section of a low pressure chamber, anode, plasma window, cathode housing, and cathodes according to embodiments disclosed and described herein;

FIG. 3 schematically depicts a cross-section of an anode, plasma window, and cathode housing according to embodiments disclosed and described herein;

FIG. 4A schematically depicts a front view of a plate having a 4-jet impingement cooling channel design according to embodiments disclosed and described herein;

FIG. 4B schematically depicts a side view of a plate with an aperture extending through the plate near the geometrical center of the plate;

FIG. 5 schematically depicts a front view of a plate have a refractory metal slug according to embodiments disclosed and described herein;

FIG. 6A graphically depicts temperature and pressure drop versus flow rate of for a plate having a 4-jet impingement cooling channel design according to embodiments disclosed and described herein;

FIG. 6B graphically depicts temperature and pressure drop versus flow rate of for a plate having two circular, parallel cooling channels;

FIG. 7A graphically depicts aperture temperature versus flow rate for a plate with the 4-jet impingement cooling channel design according to embodiments disclosed and described herein, and for a plate having two circular, parallel cooling channels; and

FIG. 7B graphically depicts cooling channel temperature versus flow rate for a plate with the 4-jet impingement cooling channel design according to embodiments disclosed and described herein, and for a plate having two circular, parallel cooling channels.

### DETAILED DESCRIPTION

Reference will now be made in detail to embodiments of cooling plates for use in plasma windows of beam accelerator systems, embodiments of which are illustrated in the accompanying drawings. Whenever possible, the same reference numerals will be used throughout the drawings to refer to the same or like parts.

According to embodiments, a plasma window is positioned in a gaseous target neutron generation system to operate as a windowless vacuum barrier to separate a low-pressure beamline and a high-pressure gaseous target chamber. The plasma window allows for systems with an increased gaseous target pressure, a shortened target length, and an increased current delivered to the target (e.g., a target gas present in the target chamber). In view of this beam accelerator systems built with plasma windows result in an increase of up to two orders of magnitude in accessible neutron flux compared to traditional beam accelerator systems.

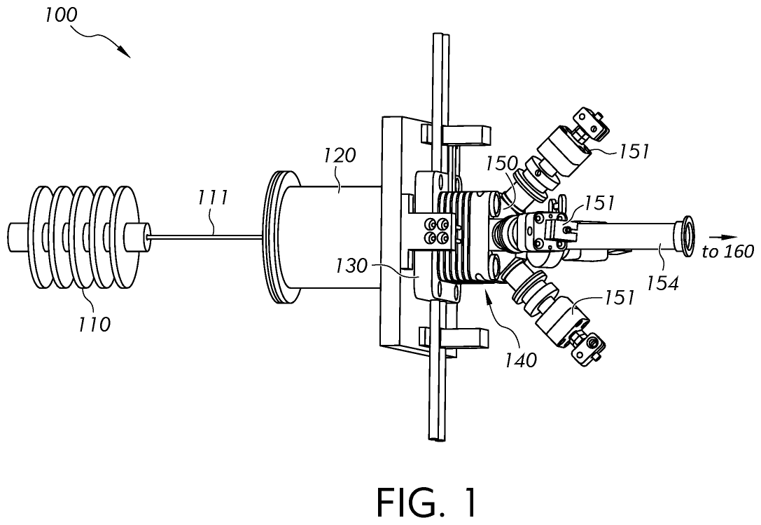

With reference to FIG. 1, an embodiment of a beam accelerator system 100 comprises an ion accelerator 110 that generates a high-energy ion beam 111 that is directed through a low-pressure chamber 120. The beam accelerator system 100 is operative to produce neutrons via fusion reaction. These neutrons may be used, for example, to perform neutron radiography, generate medical isotopes, perform transmutation of radioisotopes, such as waste radioisotopes generated during the operation of a nuclear fission power plant, and generate fusion power. In embodiments, the low-pressure chamber is operated at a vacuum or near vacuum. An anode 130, is positioned adjacent and fluidly connected to the low-pressure chamber 120 and is separated from a cathode housing 150 by the plasma window 140. The plasma window 140 is adjacent and fluidly connected to both the anode 130 and the cathode housing 150. In embodiments, the anode 130 may be an anode plate. The cathode housing 150 is configured to house a plurality of cathodes 151, which will be described in more detail below. The beam accelerator system 100 also comprises a target chamber 160 for housing a target gas, such as deuterium, tritium, helium, or argon. The target chamber 160 and the cathode housing 150 are pressurized so that the cathode housing 150 is on a high-pressure side of the beam accelerator system 100, and the anode 130 is present on a low-pressure side (e.g., vacuum side) of the beam accelerator system 100. Gases generated by the ion accelerator 101 and those present in the low-pressure chamber 120 do not travel past the anode 130 and into the plasma window 140 or cathode housing 150 because of the pressure differential between the low-pressure side of the beam accelerator system 100 and the high-pressure side of the beam accelerator system 100. It should be understood that FIG. 1 is for illustrative purposes only, and is not drawn to scale. It should be noted that in some embodiments, the position of the anode and cathode may be reversed. Without wishing to be bound by theory, it is believed that such embodiments would be beneficial when coupling with a neutron-generating target, e.g., to increase available sample volume in the high flux region.

Traditionally, accelerating ions into a gaseous target chamber (such as target chamber 160) requires large and expensive pumping infrastructure to maintain the low pressure required for the ions to be accelerated from the ion accelerator 110 while maximizing the pressure in the target chamber 160, which is adjacent and fluidly coupled to the cathode housing 150 in the embodiment depicted in FIG. 1. The lower limit for the pressure in the target chamber is generally determined by the minimum pressure required to stop the incident ion beam. The length of the target chamber 160 may influence the lower pressure limit. In embodiments, the lower limit for the pressure of the target chamber 160 may be 1 torr, 5 torr, 10 torr, 15 torr, 20 torr, 30 torr, 50 torr, 100 torr, or 500 torr. The upper limit for the pressure of the target chamber 160 is generally controlled by the ability of the pumping system to maintain the required pressure differential. Larger ion beam sizes and higher current ion beams require more pumping due to the conductance of the ion beam through a channel and into the target. Therefore, the beam size and thus total yield of a system is limited by the diameter of the channel into the target chamber.

Utilizing a plasma window 140 between the anode 130, which is at low pressure (e.g., near vacuum), and the cathode housing 150, which is at high pressure, allows for a greater pressure reduction factor relative to traditional channels, facilitating the use of larger diameter and higher power ion beams. The gains from pressure reduction also reduce the total pumping cost due to the decrease in conductance and pumping hardware required to maintain the pressure differential.

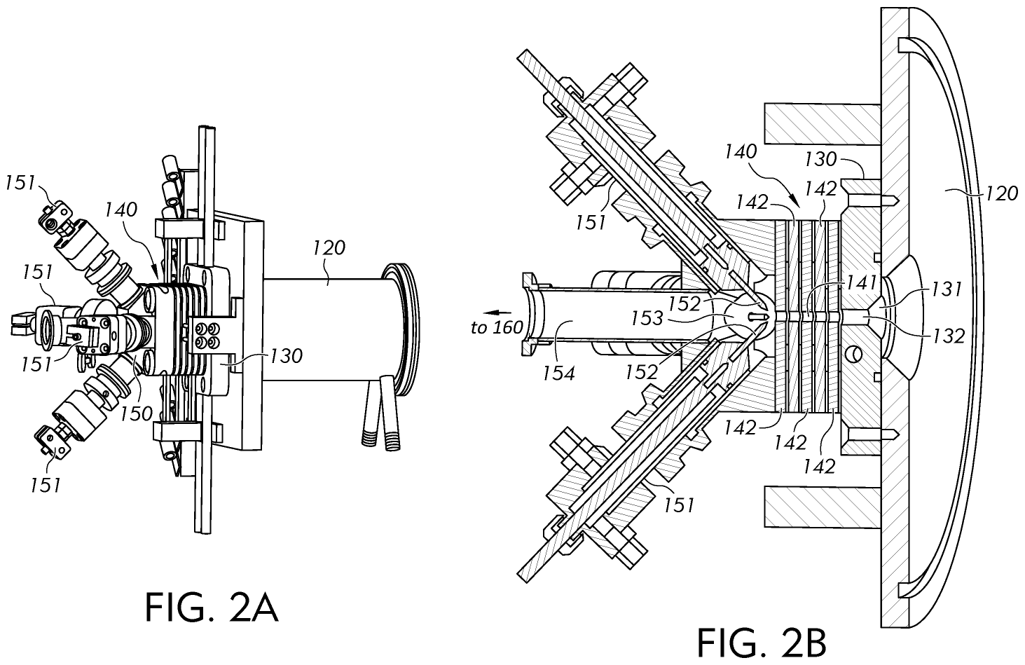

FIG. 2A is a side view of the low-pressure chamber 120, the anode 130, the plasma window 140, the cathode housing 150, and the cathodes 151. As shown in FIG. 2A, the plasma window 140 comprises a plurality of plates that are adjacent and connected to one another. In embodiments, the plasma window 140 comprises from 4 to 8 plates, such as from 5 to 7 plates, or 6 plates. As noted above, the plasma window 140 is positioned between the anode 130 and the cathode housing 150, and the plasma window 140 is connected to both the anode 130 and the cathode housing 150. The cathode housing 150 is configured to support a plurality of cathodes 151. In embodiments, the cathode housing 150 is configured to support four cathodes, three cathodes, or two cathodes. In embodiments where the cathode housing is configured to support four cathodes, the cathodes 151 may be positioned about 90° from one another in the cathode housing 150. In embodiments where the cathode housing 150 is configured to support three cathodes, the cathodes 151 may be positioned about 120° from one another, and in embodiments where the cathode housing 150 is configured to support two cathodes, the cathodes 151 may be positioned about 180° from one another.

FIG. 2B is a cross-section view of the low-pressure chamber 120, the anode 130, the plasma window 140, and the cathode housing 150 depicted in FIG. 2A. The anode 130 is, in embodiments, a grounded plate that comprises a nozzle 131 that is fluidly connected to the low-pressure chamber 120. The nozzle 131 is also fluidly connected to a channel 132 positioned in the anode 130. As will be discussed in more detail below, the nozzle 131 and the channel 132 in the anode 130 operate to funnel the ion beam from the low-pressure side of the beam accelerator system 100 to the plasma window 140. To this end, in one or more embodiments, the anode and/or the low-pressure chamber 120 are mounted to and fluidly connected with a pumping system.

With reference still to FIG. 2B, the plasma window 140 includes five adjacent plates 142 that are connected to one another and separate the anode 130 from the cathode housing 150. It should be understood that embodiments of the plasma window 140 may comprise more or less than five plates 142. Each plate 142 of the plasma window 140 comprises a circular aperture at or near the geometrical center of the plate 142. The circular aperture of each plate 142 is aligned around a central axis so that when the plurality of plates 142 are aligned and connected, the coaxial, circular apertures in the plates 142 form a plasma channel 141 through which the high-energy ion beam will travel from the anode 130 to the cathode housing 150. It should be appreciated that in embodiments the apertures in the plates 142 need not be perfectly circular and may be any shape that can accommodate the transmission of the high-energy ion beam. The plates 142 of the plasma window 140 are, in embodiments, electrically floating and are cooled with a fluid, such as water, which will be discussed in more detail below. By constructing the plates 142 to be electrically floating, the voltage gradient across the plasma channel 141 is not as steep as it would be if the plates 142 were grounded; this can aid the transmission of the high-energy ion beam across the plasma channel 141. In one or more embodiments, separators may be positioned between portions of adjacent plates 142. In embodiments, the separators may comprise a boron nitride spacer (not shown) most proximate to the plasma channel 141, a Viton O-ring surrounding the boron nitride spacer, and a PVC or PEEK spacer surrounding the Viton O-ring. In order to provide longer lifetimes in high neutron environments, brazed or diffusion bonded metal-to-metal seals may also be used as an alternative to Viton O-rings.

Still referring to FIG. 2B, the cathode housing 150 is configured to support a plurality of cathodes 151, as described above. The cathode housing 150 also comprises a cathode target region 153 that is fluidly coupled to the target chamber 160 and in which the target gas housed in the target chamber 160 is also present. Each cathode 151 comprises a cathode needle 152 that extends from the cathode 151 into the cathode target region 153. The cathodes 151 apply a voltage (e.g., a voltage in a range of from 150 V to 250 V, such as 200 V) across multiple points in the cathode target region 153 via the cathode needles 152 to initiate and/or maintain the heating and ionization of a portion of the target gas, thereby forming a plasma 310, which is viscous. In some embodiments, the cathodes 151 apply voltage to both initiate the formation of and maintain the plasma 310. However, other methods of initiating formation of the plasma 310 are contemplated, such as using one or more initiation coils, such as tesla coils, to apply the initial voltage. Such initiation coils, while not depicted, may be mounted on one or more of the plates 142 of the plasma window 140. Moreover, in embodiments comprising initiation coils, the cathodes 151 may still apply a voltage to maintain the plasma 310. The cathode target region 153 of the cathode housing 150 is fluidly coupled to the target chamber 160 by a gas inlet 154, and both the target chamber 160 and the cathode target region 153 operate at a significantly higher pressure than the anode 130 and the low-pressure chamber 120 The target chamber 160 and the cathode target region 153 may be pressurized by a pumping system or the like. It should be understood that, in some embodiments, the cathode target region 153 is a portion of the target chamber 160, that is, the portion of the target chamber 160 nearest the cathode needles 152.

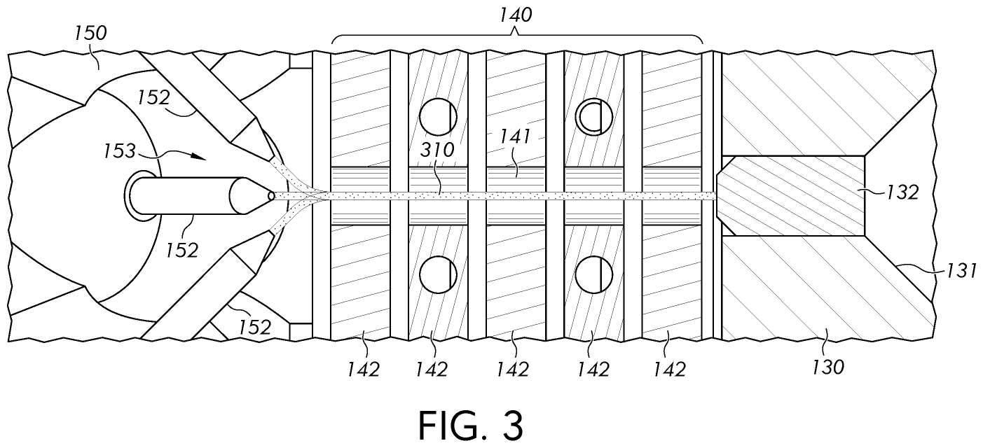

The transmission of the high-energy ion beam from the anode 130 through the plasma window 140 to the cathode housing 150 will now be described with reference to FIG. 3, which is a cross-section view of the anode 130, plasma window 140, and cathode housing 150. As mentioned above, the anode 130 may, in embodiments, be an anode plate comprising a nozzle 131 that is fluidly connected to the low-pressure chamber 120 (not shown in FIG. 3) and a channel 132 fluidly connected to the nozzle 131. The plasma window 140 depicted in FIG. 3 includes five adjacent plates 142 having circular apertures coaxially aligned to form plasma channel 141. The plasma channel 141 is fluidly connected to the channel 132 of the anode 130 and the cathode target region 153 of the cathode housing 150. Target gas is introduced into the cathode target region 153 and the plasma 310 is generated at the cathode needles 152 (or at one or more initiation coils) and the plasma 310 fills the plasma channel 141 and extends into the channel 132 in the anode 130. By filling the plasma channel 141 with the plasma 310, a pressure barrier is created between the cathode housing 150 and the anode 130. However, the ion beam from the ion accelerator (shown in FIG. 1) is capable of being transferred through the plasma 310. Therefore, the pressure differential between the high-pressure side of the beam accelerator system 100 and the low-pressure side of the beam accelerator system 100 can be maintained while still transmitting a high-energy ion beam through the beam accelerator system 100.

As described above, the plasma window 140 disclosed and described herein is effective at maintaining pressure differentials in the beam accelerator system 100, which can significantly reduce the costs (both capital and operating) and footprint associated with pumping systems needed in the beam accelerator system 100 that do not utilize one or more plasma windows 140. However, cooling a plasma window 140 once the plasma channel 141 fills with a plasma 310 is a challenge. In particular, it is conventional to use a constant power density on the plasma channel 141 regardless of the diameter of the plasma channel 141. However, as the diameter of the plasma channel 141 increases, the total power applied to the wall of the plasma channel 141 increases, causing extremely high temperatures. Accordingly, the plates 142 of the plasma window 140 may be designed to improve cooling of the plates 142 and the plasma channel 141. Such designs may incorporate cooling channels through the thickness t of the plates 142 where a cooling fluid, such as deionized water or the like, is flushed through the cooling channels, thereby extracting heat from portions of the plate 142 near the wall of the plasma channel 141 and into the cooling fluid. Important considerations in cooling channel designs include the associated pressure drop across the cooling channels as well as the cooling capacity of the cooling fluid, e.g., the maximum temperature of the wall of the plasma channel 141 under a given set of working conditions. The present disclosure provides an impingement cooling channel design for plates 142 that achieves good cooling of the plasma channel 141 with an acceptable pressure drop across the cooling channels.

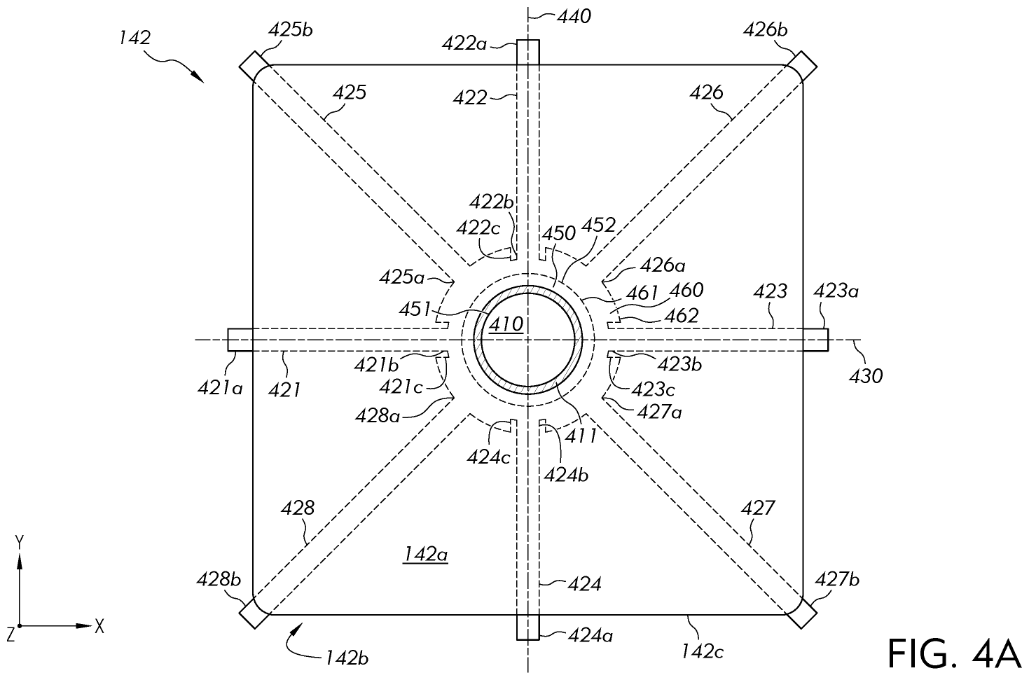

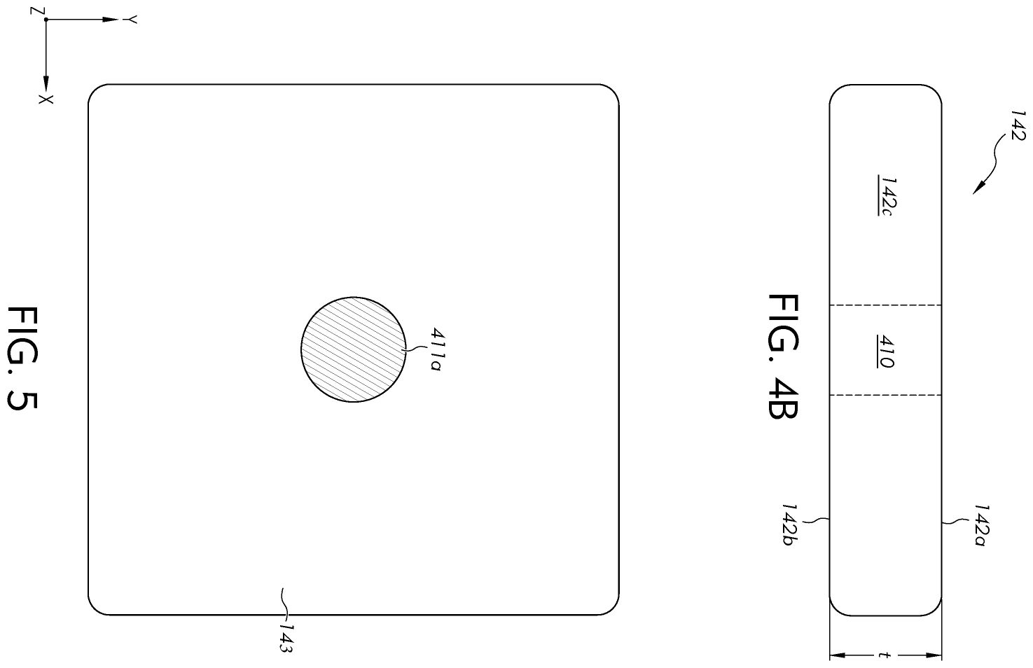

A front view of a 4-jet impingement cooling channel design of a plate 142 used in a plasma window 140 will now be described with reference to FIG. 4A. The plate 142 has a circular aperture 410 positioned near the geometrical center of the plate 142. The majority of the plate 142 is constructed from a thermally conductive metal, such as copper, silver, molybdenum, tungsten, or related alloys. In embodiments, the plate 142 is constructed from copper. Additionally, the plate can be a combination of materials. For example, the plate 142 may consist of a largely copper body with a tungsten layer near the plasma channel 141 (i.e., at the wall of the aperture 410).

As described above, when a plurality of plates 142 are placed adjacent to one another, the aperture 410 in each plate 142 aligns to form the plasma channel of the plasma window, and the plasma 130 fills the plasma channel. Accordingly, the diameter of the aperture 410 in each plate 142 is approximately the size of the ion beam that is transmitted through the plasma channel. In embodiments, the aperture 410 has a diameter that is from 1.0 mm to 10.0 mm, such as from 2.0 mm to 8.0 mm, from 3.0 mm to 7.0 mm, or from 4.0 mm to 6.0 mm. In some embodiments, the plasma window to may have a variable aperture size that could be adjusted to more closely match the properties of the ion beam. The diameter of the high energy ion beams (and in some cases, high energy electron beams) generated in beam accelerator systems are orders of magnitude larger than the sub one-millimeter diameter of electron beams used in typical, low power electron beam (e-beam) systems. Accordingly, much smaller aperture diameters could be used in typical e-beam and low energy, precision ion beam systems than in beam accelerator systems that generate high energy ion beams and, as mentioned above, the larger aperture diameters used, the more total power, and heat, is delivered to the aperture walls. That is to say, plates 142 used in plasma windows of high energy ion beam accelerator systems have entirely different cooling requirements than their counterpart components used in e-beam systems and low energy, precision ion beam systems.

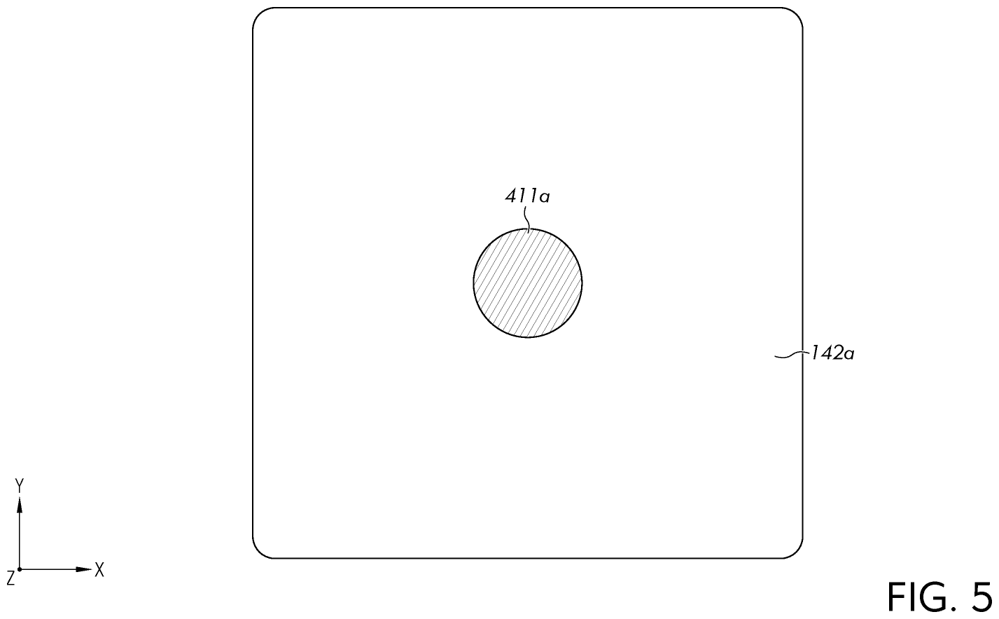

As mentioned above, the high-energy ion beam has approximately the same diameter as the plasma channel and, thereby, the ion beam has approximately the same diameter as aperture 410 of the plate 142. This can lead to significant heat loads in the plate 142, especially around the aperture 410, even when a thermally conductive metal like copper is used to form the plate 142. Moreover, portions of the plasma that fills the plasma channel may contact the inner wall of the aperture 410. Thermally conductive metals traditionally used in industry, such as copper, may not be able to withstand the temperatures caused contact with—or even close proximity to—the plasma. Accordingly, in one or more embodiments disclosed and described herein, a ring of refractory metal 411, such as tungsten or molybdenum, may be used to form the inner wall of the aperture 410 and, thereby the inner wall of the plasma channel. In such embodiments, and with reference to FIG. 5, a thermally conductive metal plate 143 (such as a plate made from copper) may be integrally formed around a cylindrical slug 411a of the refractory metal, such as by molding liquidus thermally conductive metal around the cylindrical slug 411a of refractory metal. Once the thermally conductive metal plate 143 is formed, the cylindrical slug 411a may be machined to form the aperture 410 with an inner surface of refractory metal 411.

With continued reference to FIG. 4A, and as mentioned above, a significant amount of heat is generated when the plasma fills the plasma channel, which creates a large heat load in the plate 142 around the aperture 410. This heat load can lead to poor performance or even failure of the plate 142.

FIG. 4B shows a side view of plate 142 containing only the aperture 410 (i.e., without the cooling channel design). The plate 142 comprises a first surface 142a and a second surface 142b that is substantially parallel to the first surface 142a. The thickness t of the plate 142 is defined by the distance between the first surface 142a and the second surface 142b. An edge 142c extends from the first surface 142a to the second surface 142b and constitutes a perimeter of the plate 142. As such, the edge 142c is present on all four sides of the plate 142 depicted in FIG. 4A.

The 4-jet impingement cooling channel design is now described in more detail with continued reference to FIG. 4A. The plate 142 shown in FIG. 4A is generally square shaped, although any suitable shape may be used. The plate 142 comprises a central wall 450 surrounding the aperture 410. In some embodiments, the central wall 450 is annular shaped such that an outer facing surface of the central wall 450 retains an equal distance from the aperture 410 at all circumferential positions. However, it should be understood that embodiments are contemplated comprising a polygonal-shaped central wall 450, such as a rectilinear-shaped central wall 450. In embodiments where refractory metal 411 makes up the inner wall of the aperture 410, the central wall 450 includes the refractory metal 411. The central wall 450 comprises an inner facing surface 451 and an outer facing surface 452. The inner facing surface 451 of the central wall 450 may also define a wall of the aperture 410. In embodiments wherein the central wall 450 is annular shaped, the inner facing surface 451 may be an inner annular surface and the outer facing surface 452 may be an outer annular surface. The width of the central wall 450 may be defined by the radial distance between the inner facing surface 451 and the outer facing surface 452. In embodiments, the width of the central wall 450 is from 4 mm to 16 mm, 6 mm to 14 mm, or from 8 mm to 12 mm. In one embodiment, the width of the central wall 450 is 9.525 mm.

Surrounding the central wall 450 is a cooling chamber 460. The cooling chamber 460 may comprise an inner surface, e.g., inner annular surface 461, and an outer surface, e.g., outer annular surface 462. A width of the cooling chamber 460 may be defined by the radial distance between the inner annular surface 461 and the outer annular surface 462. The radius of the outer annular surface 462 of the cooling chamber 460 is larger than the radius of the inner annular surface 461 of the cooling chamber 460. The inner annular surface 461 of the cooling chamber 460 may also define the outer annular surface of the central wall 450 (e.g., when the central wall 450 is annular shaped). In embodiments, the width of the cooling chamber 460 is from 2 mm to 16 mm, 4 mm to 14 mm, or from 6 mm to 12 mm.

The central wall 450 and aperture 410 extend from the first surface 142a to the second surface 142b. However, the cooling chamber 460 is bounded by the first surface 142a and the second surface 142b. In other words, the cooling chamber 460 runs through a thickness t of the plate 142.

A first impingement channel 421, a second impingement channel 422, a third impingement channel 423, and a fourth impingement channel 424 enter the plate 142 through the edge 142c of the plate 142 between the first surface 142a and the second surface 142b, and extend toward the aperture 410. The first impingement channel 421, the second impingement channel 422, the third impingement channel 423, and the fourth impingement channel 424 enter the plate 142 at separate sides of the plate 142, with the first impingement channel 421 entering from a left side of the plate 142, the second impingement channel 422 entering from a top side of the plate, the third impingement channel 423 entering from a right side of the plate, and the fourth impingement channel entering from a bottom side of the plate, with reference to FIG. 4A. Like the cooling chamber 460, each of the first impingement channel 421, the second impingement channel 422, the third impingement channel 423, and the fourth impingement channel 424 are bounded by the first surface 142a and the second surface 142b. That is to say, each of the first impingement channel 421, the second impingement channel 422, the third impingement channel 423, and the fourth impingement channel 424 extend toward the aperture 410 in a substantially parallel fashion with respect to the first surface 142a and the second surface 142b and run through the thickness t of the plate 142.

The first impingement channel 421 enters the plate 142 from a first side (i.e., left in the −x direction) of the plate 142 and at inlet 421a of the first impingement channel 421, and terminates within the cooling chamber 460 at outlet 421b. The second impingement channel 422 enters the plate 142 from a second side (i.e., top in the +y direction) of the plate 142 and at inlet 422a of the second impingement channel 422, and terminates within the cooling chamber 460 at outlet 422b. The third impingement channel 423 enters the plate 142 from a third side (i.e., right in the +x direction) of the plate 142 and at inlet 423a of the third impingement channel 423, and terminates within the cooling chamber 460 at outlet 423b. The fourth impingement channel 424 enters the plate 142 from a fourth side (i.e., bottom in the-y direction) of the plate 142 and at inlet 424a of the fourth impingement channel 424, and terminates within the cooling chamber 460 at outlet 424b. The respective portions of the first impingement channel 421, the second impingement channel 422, the third impingement channel 423, and the fourth impingement channel 424 that extend into the cooling chamber 460 are respectively referred to as the first impingement channel wall 421c, the second impingement channel wall 422c, the third impingement channel wall 423c, and fourth impingement channel wall 424c. In one embodiment, each of the first impingement channel 421, the second impingement channel 422, the third impingement channel 423, and the fourth impingement channel 424 terminate at the outer annular surface 462 of the cooling chamber 460.

The first impingement channel 421, the second impingement channel 422, the third impingement channel 423, and the fourth impingement channel 424 may terminate within the cooling chamber 460 at the same distance away from the inner annular surface 461 of the cooling chamber 460. This distance is herein referred to as the impingement separation gap and may be from 2 mm to 8 mm, 3 mm to 7 mm, or 4 mm to 6 mm.

In embodiments, the longitudinal axes of the first impingement channel 421 and the third impingement channel 423 are positioned at about a centerline 430 that horizontally bisects a cross-section of the aperture 410 (i.e., in the x-direction), and the longitudinal axes of the second impingement channel 422 and the fourth impingement channel 424 are positioned at about a centerline 440 that vertically bisects a cross-section of the aperture 410 (i.e., in the y-direction). Accordingly, the first impingement channel 421 and the third impingement channel 423 may be substantially perpendicular to the second impingement channel 422 and the fourth impingement channel 424. The first impingement channel 421, the second impingement channel 422, the third impingement channel 423, and the fourth impingement channel 424 are thus radially arranged and separated from each other by 90°.

The plate 142 with the 4-jet impingement cooling channel design shown in FIG. 4A further comprises a first return channel 425, a second return channel 426, a third return channel 427, and a fourth return channel 428, each of which enter the plate 142 at the edge 142c of the plate 142 between the first surface 142a and the second surface 142b, and extend toward the aperture 410. Like the cooling chamber 460, each of the first return channel 425, the second return channel 426, the third return channel 427, and the fourth return channel 428 are bounded by the first surface 142a and the second surface 142b. That is to say, each of the first return channel 425, the second return channel 426, the third return channel 427, and the fourth return channel 428 extend toward the aperture 410 in a substantially parallel fashion with respect to the first surface 142a and the second surface 142b and run through the thickness t of the plate 142.

The first return channel 425 enters the plate 142 at an outlet 425b, positioned at an upper left corner of the plate, and extends toward the aperture 410 at an approximately 45° angle with respect to both the first impingement channel 421 and the second impingement channel 422, and terminates at inlet 425a at the outer annular wall 462 of the cooling chamber 460. The second return channel 426 enters the plate 142 at an outlet 426b, positioned at an upper right corner of the plate, and extends toward the aperture 410 at an approximately 45° angle with respect to both the second impingement channel 422 and the third impingement channel 423, and terminates at inlet 426a at the outer annular wall 462 of the cooling chamber 460. The third return channel 427 enters the plate 142 at an outlet 427b, positioned at a lower right corner of the plate, and extends toward the aperture 410 at an approximately 45° angle with respect to both the third impingement channel 423 and the fourth impingement channel 424, and terminates at inlet 427a at the outer annular wall 462 of the cooling chamber 460. The fourth return channel 428 enters the plate 142 at an outlet 428b, positioned at a lower left corner of the plate, and extends toward the aperture 410 at an approximately 45° angle with respect to both the fourth impingement channel 424 and the first impingement channel 421, and terminates at inlet 428a at the outer annular wall 462 of the cooling chamber 460. Accordingly, the first return channel 425 and the third return channel 427 may be substantially perpendicular to the second return channel 426 and the fourth return channel 428. The first return channel 425, the second return channel 426, the third return channel 427, and the fourth return channel 428 are thus radially arranged and separated from each other by 90°. Moreover, each of the first impingement channel 421, the second impingement channel 422, the third impingement channel 423, and the fourth impingement channel 424 are radially adjacent to two return channels, and each of the first return channel 425, the second return channel 426, the third return channel 427, and the fourth return channel 428 are radially adjacent to two impingement channels.

It should be understood that in some embodiments, the plates 142 are not square and the angular separation of the impingement channels and returns channels could be modified accordingly. For example, in an embodiment comprising a hexagonal plate, three impingement channels may be separated from each other by 120° and three return channels may be separated from each other by 120° and arranged in an alternating fashion with the three impingement channels. In such an embodiment, each of the three impingement channels would be radially adjacent to two return channels and separated from each of the two adjacent return channels by an angle of approximately 60°. Likewise, each of the three return channels would be radially adjacent to two impingement channels and separated from the two adjacent impingement channels by an angle of approximately 60°.

The operation of the 4-jet impingement cooling channel design shown in FIG. 4A is now discussed in more detail. As discussed above, the wall of the aperture (i.e., the inner facing surface of the central wall) is exposed to the plasma that fills that the plasma channel and is subjected to a large heat load. The central wall 450 thermally couples the wall of the aperture (i.e., the inner facing surface 451 of the central wall) with the inner annular surface 461 of the cooling chamber 460, which operates as an impingement target for jets of cooling fluid emerging from the first impingement channel 421, the second impingement channel 422, the third impingement channel 423, and the fourth impingement channel 425. In operation, cooling fluid is directed from each impingement channel in the form of a jet which impinges the inner annular surface 461 of the cooling chamber 460, which is thermally coupled with the wall of the aperture via the central wall 450. Accordingly, heated cooling fluid emerging from the impingement channels removes heat from the inner annular surface 461 of the cooling chamber 460 and thereby removes heat from the wall of the aperture, for example, when the plasma is present in the plasma channel. After impinging the inner annular surface 461 of the cooling chamber 460, the heated cooling fluid exits the cooling chamber 460 through the first return channel 425, the second return channel 426, the third return channel 427, and the fourth return channel 428.

In the embodiment shown in FIG. 4A, each of the first impingement channel wall 421c, the second impingement channel wall 422c, the third impingement channel wall 423c, and the fourth impingement channel wall 424c extends into the cooling chamber 460 and terminate at a point offset from the inner annular surface 461 of the cooling chamber 460. The first impingement channel wall 421c, the second impingement channel wall 422c, the third impingement channel wall 423c, and the fourth impingement channel wall 424c may help direct the jets of cooling fluid at the inner annular surface 461 of the cooling chamber 460. By focusing jets of cooling fluid directly at the central wall 450, which acts as a heat sink between the aperture wall and the cooling chamber 460, the impingement cooling channel design creates a thin boundary layer at the inner annular surface 461 of the cooling chamber 460 which leads to a high heat transfer coefficient between the cooling fluid and the inner annular surface 461 of the cooling chamber 460.

Various ratios with regards to the size of features of the impingement channel cooling design may be controlled so as to optimize the cooling capacity while maintaining acceptable pressure drops across the impingement channel cooling design. For example, the ratio between the impingement separation gap and the width of the central wall 450 may be from 0.25 to 2.0, from 0.5 to 1.5, or from 0.75 to 1.25. The ratio between the width of the cooling chamber 460 and the width of the central wall 450 may be from 1.0 to 4.0, from 1.5 to 3.5, or from 2.0 to 3.0. The width of the cooling chamber 460 may also be less than the width of the central wall 450.

In some embodiments, the plates 142 may be unitary without seams or welding artifacts. By machining the cooling channels through the thickness t of the plate 142 the integrity of the plate 142 is not compromised by seams or welding—which can cause weak points within the plate 142—traditionally present in plasma window plates.

According to one or more embodiments, the impingement channels and the return channels have a circular cross section with diameters sized according to the amount of cooling fluid throughput that is desired. In other embodiments, the impingement channels and the return channels may have a cross-section that is elliptical, square, rectangular, pentagonal, hexagonal, or octagonal. Of course, the cross-sectional dimensions, such as the diameter, of the impingement channels and the return channels is limited by the thickness t of the plate 142.

It should be understood that although the impingement cooling channel design shown in FIG. 4A comprises four impingement channels and four return channels, a greater or fewer number of impingement channels and return channels could be employed. For example, in some embodiments, the impingement cooling channel design comprises two impingement channels and two return channels, three impingement channels and three return channels, five impingement channels and five return channels, or six impingement channels and six return channels.

In any of the embodiments disclosed and described herein, the impingement channels and return channels may have a cross-sectional diameter that is greater than or equal to 0.5 mm and less than or equal to 5.0 mm, greater than or equal to 1.0 mm and less than or equal to 5.0 mm, greater than or equal to 2.5 mm and less than or equal to 5.0 mm, greater than or equal to 4.0 mm and less than or equal to 5.0 mm, greater than or equal to 0.5 mm and less than or equal to 3.0 mm, greater than or equal to 1.0 mm and less than or equal to 3.0 mm, or greater than or equal to 0.5 mm and less than or equal to 2.0 mm.

It should be understood that the plasma window 140 may be cooled using any of the embodiments described herein. Indeed, operation of the beam accelerator system 100 may comprise generating the plasma 310 in the plasma channel 141. The plasma 310 may by generated by applying a voltage to a target gas (which is housed in the target chamber 160 and the cathode target region 153 and may comprise deuterium, tritium, argon, or helium) thereby heating and ionizing a portion of the target gas to form the plasma 310. In some embodiments, the input voltage is applied by the cathodes 151. In other embodiments, the input voltage is applied by one or more initiation coils, such as tesla coils, which may be mounted on one or more of the plates 142. The method next comprises directing the ion beam 111, which is generated by the ion accelerator 110, from the low-pressure chamber 120 through the plasma 130 disposed in the plasma channel 141 of the plasma window 140 and into the target chamber 160, wherein a target gas is housed. In the target chamber 160, the ion beam 111 may interact with the target gas to produce neutrons via fusion reactions. The method also includes cooling the plasma window 140, specifically the plates 142 of the plasma window 140, which are heated by the plasma 310 in the plasma channel 141. As described above with respect to FIGS. 4A and 4B, the plates 142 may be cooled by directing the cooling fluid through the one or more impingement channels 421-424 such that the cooling fluid impinges the central wall 450, transferring heat from the central wall 450 to the cooling fluid, which then flows as a heated cooling fluid into the one or more return channels 425-428.

As used herein, terms such as “substantially,” “approximately,” and the like refer to the subsequently listed property or measurement within normal manufacturing tolerances and imperfections in the relevant field.

According to a first aspect of the present disclosure, a beam accelerator system comprises: an ion accelerator that generates an ion beam; a low-pressure chamber; an anode adjacent and fluidly connected to the low-pressure chamber; a plasma window adjacent and fluidly connected to the anode, and a cathode housing adjacent and fluidly connected to the plasma window, wherein the plasma window comprises a plurality of cooling plates, each cooling plate comprises an aperture that is aligned with an aperture in one or more adjacent cooling plate to form a plasma channel, and one or more cooling plates of the plurality of cooling plates comprises: a central wall surrounding the aperture; a cooling chamber surrounding the central wall; one or more impingement channels entering the cooling plate from an outer edge of the cooling plate and extending toward the aperture to the cooling chamber, and one or more return channels entering the cooling plate from the outer edge of the cooling plate and extending toward the aperture to the cooling chamber, wherein each of the one or more impingement channels are configured to provide an entrance pathway for cooling fluid to enter the cooling chamber and each of the one or more return channels are configured to provide an exit pathway for heated fluid to exit the cooling chamber.

A second aspect may include the first aspect, wherein the aperture is positioned at the center of each of the plurality of cooling plates and extends through a thickness of each of the plurality of cooling plates.

A third aspect may include the first or second aspects, wherein each of the one or more impingement channels comprises an impingement channel wall that extends into and terminates within the cooling chamber.

A fourth aspect may include any of the previous aspects, wherein: the central wall comprises a ring shape; the cooling chamber comprises an inner annular surface and an outer annular surface; the inner annular surface of the cooling chamber defines an outer annular surface of the central wall; and each of the one or more return channels terminates at the outer annular surface of the cooling chamber.

A fifth aspect may include the fourth aspect, wherein the cooling chamber comprises a width defined by a radial distance between the inner annular surface of the cooling chamber and the outer angular surface of the cooling chamber, and wherein the width of the cooling chamber is from 2 mm to 16 mm.

A sixth aspect may include the fourth aspect, wherein the cooling chamber comprises a width defined by a radial distance between the inner annular surface of the cooling chamber and the outer annular surface of the cooling chamber; the central wall comprises an inner annular surface, an outer annular surface, and a width defined by a radial distance between the inner annular surface of the central wall and the outer annular surface of the central wall; and wherein a ratio between the width of the cooling chamber and the width of the central wall is from 1.0 to 4.0.

A seventh aspect may include any of the previous aspects, wherein each of the one or more impingement channels and each of the one or more return channels are radially arranged and in an alternating fashion around the aperture.

A eighth aspect may include any of the first through the sixth aspects, wherein the one or more impingement channels comprises four impingement channels that are radially arranged and separated from each other by 90°; and the one or more return channels comprises four return channels that are radially arranged and separated from each other by 90°, wherein: each of the four impingement channels is radially adjacent to two return channels and each of the four return channels is radially adjacent to two impingement channels; and each of the four impingement channels is radially spaced from adjacent return channels by 45°.

A ninth aspect may include any of the previous aspects, wherein the one or more cooling plate in the plurality of cooling plates is a unitary plate.

A tenth aspect may include any of the previous aspects, wherein the plurality of cooling plates are formed from a thermally conductive material selected from the group consisting of copper, silver, aluminum, and tungsten.

A eleventh aspect may include any of the previous aspects, wherein an inner wall of the aperture is formed from a refractory material selected from tungsten or molybdenum.

A twelfth aspect may include any of the first through third aspects, the fifth aspect, or any of the seventh through eleventh aspects, wherein the central wall is a ring shape and comprises an inner annular surface, an outer annular surface, and a width defined by a radial distance between the inner annular surface of the central wall and the outer annular surface of the central wall, and wherein the width of the central wall is from 4 mm to 16 mm.

A thirteenth aspect may include the fourth aspect, wherein the central wall comprises an inner annular surface, an outer annular surface, and a width defined by a radial distance between the inner annular surface of the central wall and the outer annular surface of the central wall, and wherein the width of the central wall is from 4 mm to 16 mm.

A fourteenth aspect may include the sixth aspect, wherein the width of the central wall is from 4 mm to 16 mm.

A fifteenth aspect may include any of the first through third aspects, the fifth aspect, or any of the seventh through eleventh aspects, further comprising: an impingement separation gap defined by a radial distance between a termination point of each of the one or more impingement channels within the cooling chamber and an inner annular surface of the cooling chamber, wherein. the central wall is a ring shape and comprises an inner annular surface, an outer annular surface, and a width defined by a radial distance between the inner annular surface of the central wall and the outer annular surface of the central wall, and wherein a ratio between the impingement separation gap and the width of the central wall is from 0.25 to 2.0.

A sixteenth aspect may include the fourth aspect, further comprising an impingement separation gap defined by a radial distance between a termination point of each of the one or more impingement channels within the cooling chamber and the inner annular surface of the cooling chamber, wherein the central wall comprises an inner annular surface, an outer annular surface, and a width defined by a radial distance between the inner annular surface of the central wall and the outer annular surface of the central wall, and wherein a ratio between the impingement separation gap and the width of the central wall is from 0.25 to 2.0.

A seventeenth aspect may include the sixth or any one of the twelfth through fourteenth aspects, further comprising an impingement separation gap defined by a radial distance between a termination point of each of the one or more impingement channels within the cooling chamber and the inner annular surface of the cooling chamber, wherein a ratio between the impingement separation gap and the width of the central wall is from 0.25 to 2.0.

An eighteenth aspect may include any one of the first through fourteenth aspects, further comprising an impingement separation gap defined by a radial distance between a termination point of each of the one or more impingement channels within the cooling chamber and an inner annular surface of the cooling chamber, wherein the impingement separation gap is from 2 mm to 8 mm.

A nineteenth aspect may include any one of the fifteenth through seventeenth aspects, wherein the impingement separation gap is from 2 mm to 8 mm.

According to a twentieth aspect of the present disclosure, a method comprises: generating a plasma in a plasma channel of a plasma window, wherein: the plasma window is positioned between and fluidly coupled to an anode and a cathode housing, a plurality of cathodes are housed in the cathode housing; the plasma window comprises a plurality of cooling plates, each cooling plate comprises an aperture that is aligned with an aperture in one or more adjacent cooling plate to form the plasma channel, and one or more cooling plates of the plurality of cooling plates comprises: a central wall surrounding the aperture; a cooling chamber surrounding the central wall; one or more impingement channels entering the cooling plate from an outer edge of the cooling plate and extending toward the aperture to the cooling chamber; and one or more return channels entering the cooling plate from the outer edge of the cooling plate and extending toward the aperture to the cooling chamber; directing an ion beam generated by an ion accelerator from a low-pressure chamber through the plasma disposed in the plasma channel of the plasma window and into a target chamber, wherein the target chamber houses a target gas; and directing a cooling fluid through the one or more impingement channels such that the cooling fluid impinges the central wall, transferring heat from the central wall to the cooling fluid, which then flows as a heated cooling fluid into the one or more return channels.

A twenty-first aspect may include the twentieth aspect, wherein generating the plasma in the plasma channel comprises applying an input voltage to the target gas, thereby heating and ionizing a portion of the target gas to form the plasma.

A twenty-second aspect may include the twentieth or the twenty-first aspects, wherein the ion beam interacts with the target gas in the target chamber to produce neutrons via a fusion reaction.

A twenty-third aspect may include any one of the twentieth through the twenty-second aspects, wherein the central wall comprises a ring shape; the cooling chamber comprises an inner annular surface and an outer annular surface; the inner annular surface of the cooling chamber defines an outer angular surface of the central wall; and each of the one or more return channels terminates at the outer annular surface of the cooling chamber.

A twenty-fourth aspect may include any one of the twentieth through the twenty-third aspects, wherein each of the one or more impingement channels and each of the one or more return channels are radially arranged and in an alternating fashion around the aperture.

A twenty-fifth aspect may include any one of the twentieth through the twenty-fourth aspects, wherein: the plurality of cooling plates are formed from a thermally conductive material selected from the group consisting of copper, silver, aluminum, and tungsten; and an inner wall of the aperture is formed from a refractory material selected from tungsten or molybdenum.

### EXAMPLES

Embodiments will be further clarified by the following examples.

The Examples provided below were modeled using COMSOL software (version 6.0).

### Example 1

A plate having a 4-jet impingement cooling channel design as shown in FIG. 4A was modeled where the aperture diameter was set to 10 mm; the aperture power was set to 1 kW/cm²; the width of the cooling chamber was set to 3 mm; the width of the central wall was set to 9.525 mm; and the cooling fluid was set to be water with an inlet temperature of 20° C.

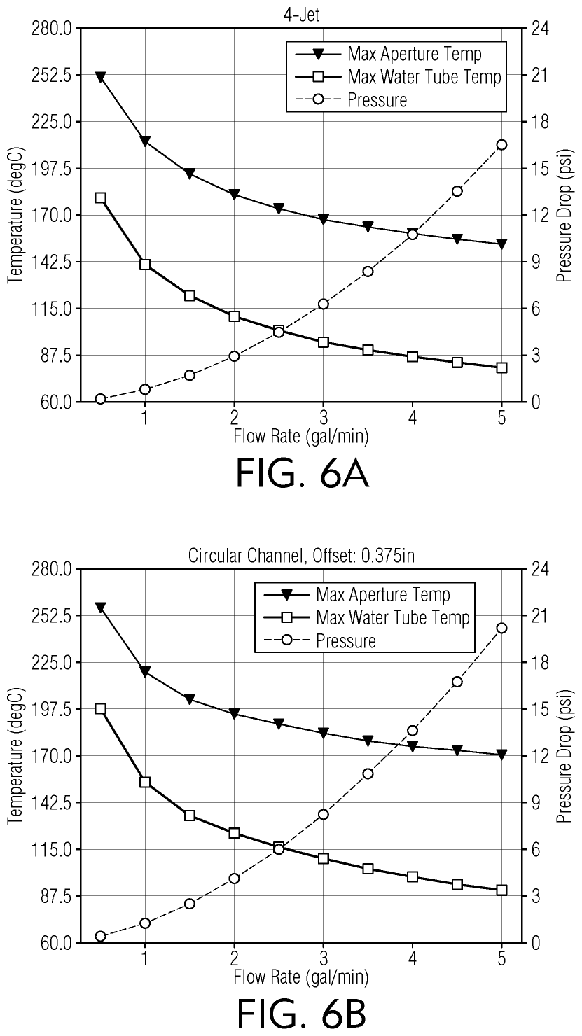

FIG. 6A shows the results of the simulation of the 4-jet impingement channel design conducted in accordance with the above parameters.

The graph in FIG. 6A provides the temperature (° C.) on the left y-axis versus flow (gal/min) of cooling water on the x-axis for the maximum aperture temperature and the maximum cooling channel temperature. The graph in FIG. 6A provides the pressure drop (psi) in the cooling channels on the right y-axis versus flow (gal/min) of cooling water on the x-axis. As shown in FIG. 6A the pressure drop starts to increase rapidly at flow rates between 2.5 gal/min and 3.0 gal/min, while the aperture temperature and the cooling channel temperature level off around flow rates between 2.5 gal/min and 3.0 gal/min.

### Comparative Example 1

A plate having a cooling channel design consisting of two circular, parallel cooling channels, one on each side of the aperture, was modeled where the aperture diameter was set to 10 mm; the aperture power was set to 1 kW/cm²; the cooling channel diameter was set to 3 mm; the cooling channel was offset from the aperture by 9.525 mm; and the cooling fluid was set to be water with an inlet temperature of 20° C. This comparative cooling channel design will be referred to as the “two-channel cooling plate.”

FIG. 6B shows the results of the simulation of the two-channel cooling plate.

The graph in FIG. 6B provides the temperature (° C.) on the left y-axis versus flow (gal/min) of cooling water on the x-axis for the maximum aperture temperature and the maximum cooling channel temperature. The graph in FIG. 6B provides the pressure drop (psi) in the cooling channels on the right y-axis versus flow (gal/min) of cooling water on the x-axis.

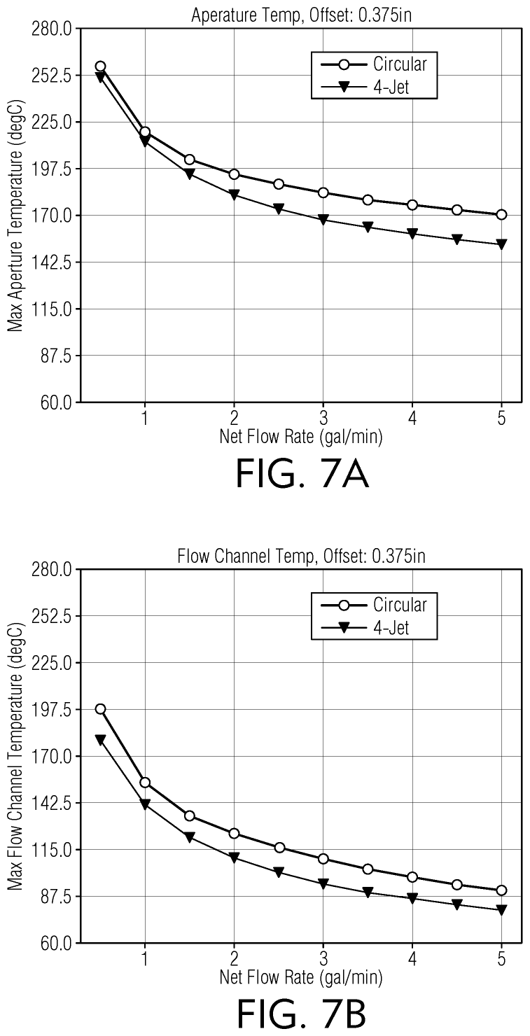

FIGS. 7A and 7B graphically depict the results of the above simulations. In FIGS. 7A and 7B, the results of the 4-jet impingement cooling channel design are indicated as “4-Jet” and the results of the two-channel cooling plate are indicated as “Circular.”

FIG. 7A graphically depicts the max aperture temperature (° C.) along the y-axis versus flow rate (gal/min) along the x-axis. FIG. 7B graphically depicts the max cooling channel temperature along the y-axis versus flow rate (gal/min) along the x-axis.

As can be seen in FIG. 7A, the 4-jet impingement cooling channel design achieves a lower maximum aperture temperature across the spectrum of tested flow rates through the cooling channel design. As the flow rate increases from 1 gal/min to 3 gal/min, the cooling performance of the 4-jet impingement cooling channel increases rapidly with respect to the two-channel cooling plate. FIG. 7B shows a similar improvement in performance of the 4-jet impingement cooling channel design with respect to the two-channel cooling plate. The 4-jet impingement cooling channel design shows a lower maximum flow channel temperature across the spectrum of tested flow rates.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. A beam accelerator system comprising:
an ion accelerator that generates an ion beam;
a low-pressure chamber;
an anode adjacent and fluidly connected to the low-pressure chamber;
a plasma window adjacent and fluidly connected to the anode; and
a cathode housing adjacent and fluidly connected to the plasma window, wherein
the plasma window comprises a plurality of cooling plates, each cooling plate comprises an aperture that is aligned with an aperture in one or more adjacent cooling plate to form a plasma channel, and
one or more cooling plates of the plurality of cooling plates comprises:
a central wall surrounding the aperture;
a cooling chamber surrounding the central wall;
one or more impingement channels entering the cooling plate from an outer edge of the cooling plate and extending toward the aperture to the cooling chamber; and
one or more return channels entering the cooling plate from the outer edge of the cooling plate and extending toward the aperture to the cooling chamber, wherein each of the one or more impingement channels are configured to provide an entrance pathway for cooling fluid to enter the cooling chamber and each of the one or more return channels are configured to provide an exit pathway for heated fluid to exit the cooling chamber.

2. The beam accelerator system of claim 1, wherein the aperture is positioned at the center of each of the plurality of cooling plates and extends through a thickness of each of the plurality of cooling plates.

3. The beam accelerator system of claim 1, wherein each of the one or more impingement channels comprises an impingement channel wall that extends into and terminates within the cooling chamber.

4. The beam accelerator system of claim 1, wherein:
the central wall comprises a ring shape;
the cooling chamber comprises an inner annular surface and an outer annular surface;
the inner annular surface of the cooling chamber defines an outer annular surface of the central wall; and
each of the one or more return channels terminates at the outer annular surface of the cooling chamber.

5. The beam accelerator system of claim 4, wherein the cooling chamber comprises a width defined by a radial distance between the inner annular surface of the cooling chamber and the outer annular surface of the cooling chamber, and wherein the width of the cooling chamber is from 2 mm to 16 mm.

6. The beam accelerator system of claim 4, wherein
the cooling chamber comprises a width defined by a radial distance between the inner annular surface of the cooling chamber and the outer annular surface of the cooling chamber;
the central wall comprises an inner annular surface, an outer annular surface, and a width defined by a radial distance between the inner annular surface of the central wall and the outer annular surface of the central wall; and
wherein a ratio between the width of the cooling chamber and the width of the central wall is from 1.0 to 4.0.

7. The beam accelerator system of claim 1, wherein each of the one or more impingement channels and each of the one or more return channels are radially arranged and in an alternating fashion around the aperture.

8. The beam accelerator system of claim 1, wherein
the one or more impingement channels comprises four impingement channels that are radially arranged and separated from each other by 90°; and
the one or more return channels comprises four return channels that are radially arranged and separated from each other by 90°, wherein:
each of the four impingement channels is radially adjacent to two return channels and each of the four return channels is radially adjacent to two impingement channels; and
each of the four impingement channels is radially spaced from adjacent return channels by 45°.

9. The beam accelerator system of claim 1, wherein the one or more cooling plate in the plurality of cooling plates is a unitary plate.

10. The beam accelerator system of claim 1, wherein the plurality of cooling plates are formed from a thermally conductive material selected from the group consisting of copper, silver, aluminum, and tungsten.

11. The beam accelerator system of claim 1, wherein an inner wall of the aperture is formed from a refractory material selected from tungsten or molybdenum.

12. The beam accelerator system of claim 1, wherein the central wall is a ring shape and comprises an inner annular surface, an outer annular surface, and a width defined by a radial distance between the inner annular surface of the central wall and the outer annular surface of the central wall, and wherein the width of the central wall is from 4 mm to 16 mm.

13. The beam accelerator system of claim 1, further comprising:
an impingement separation gap defined by a radial distance between a termination point of each of the one or more impingement channels within the cooling chamber and an inner annular surface of the cooling chamber, wherein:
the central wall is a ring shape and comprises an inner annular surface, an outer annular surface, and a width defined by a radial distance between the inner annular surface of the central wall and the outer annular surface of the central wall, and wherein
a ratio between the impingement separation gap and the width of the central wall is from 0.25 to 2.0.

14. The beam accelerator system of claim 1, further comprising an impingement separation gap defined by a radial distance between a termination point of each of the one or more impingement channels within the cooling chamber and an inner annular surface of the cooling chamber, wherein the impingement separation gap is from 2 mm to 8 mm.

15. A method comprising:
generating a plasma in a plasma channel of a plasma window, wherein:
the plasma window is positioned between and fluidly coupled to an anode and a cathode housing,
a plurality of cathodes are housed in the cathode housing;
the plasma window comprises a plurality of cooling plates, each cooling plate comprises an aperture that is aligned with an aperture in one or more adjacent cooling plate to form the plasma channel, and
one or more cooling plates of the plurality of cooling plates comprises:
a central wall surrounding the aperture;
a cooling chamber surrounding the central wall;
one or more impingement channels entering the cooling plate from an outer edge of the cooling plate and extending toward the aperture to the cooling chamber; and
one or more return channels entering the cooling plate from the outer edge of the cooling plate and extending toward the aperture to the cooling chamber;
directing an ion beam generated by an ion accelerator from a low-pressure chamber through the plasma disposed in the plasma channel of the plasma window and into a target chamber, wherein the target chamber houses a target gas; and
directing a cooling fluid through the one or more impingement channels such that the cooling fluid impinges the central wall, transferring heat from the central wall to the cooling fluid, which then flows as a heated cooling fluid into the one or more return channels.

16. The method of claim 15, wherein generating the plasma in the plasma channel comprises applying an input voltage to the target gas, thereby heating and ionizing a portion of the target gas to form the plasma.

17. The method of claim 15, wherein the ion beam interacts with the target gas in the target chamber to produce neutrons via a fusion reaction.

18. The method of claim 15, wherein:
the central wall comprises a ring shape;
the cooling chamber comprises an inner annular surface and an outer annular surface;
the inner annular surface of the cooling chamber defines an outer annular surface of the central wall; and
each of the one or more return channels terminates at the outer annular surface of the cooling chamber.

19. The method of claim 15, wherein each of the one or more impingement channels and each of the one or more return channels are radially arranged and in an alternating fashion around the aperture.

20. The method of claim 15, wherein:
the plurality of cooling plates are formed from a thermally conductive material selected from the group consisting of copper, silver, aluminum, and tungsten; and
an inner wall of the aperture is formed from a refractory material selected from tungsten or molybdenum.
